(19) United States
(12) Patent Application Publication
(10) Pub. No.: US 2015/0206997 A1
(43) Pub. Date: Jul. 23, 2015

(54) MULTI-JUNCTION SOLAR CELLS WITH RECESSED THROUGH-SUBSTRATE VIAS

(71) Applicant: SOLAR JUNCTION CORPORATION, SAN JOSE, CA (US)

(72) Inventors: ONUR FIDANER, HOUSTON, TX (US); MICHAEL WEST WIEMER, CAMPBELL, CA (US); LAN ZHANG, PALO ALTO, CA (US); EWELINA LUCOW, LOS GATOS, CA (US)

(21) Appl. No.: 14/672,571

(22) Filed: Mar. 30, 2015

Related U.S. Application Data
(63) Continuation-in-part of application No. 14/213,334, filed on Mar. 14, 2014.
Application No. 14/213,334 is a continuation-in-part of application No. 13/856,573, filed on Apr. 4, 2013.
(60) Provisional application No. 61/794,293, filed on Mar. 15, 2013.
(60) Provisional application No. 61/621,277, filed on Apr. 6, 2012.

(51) Int. Cl. H01L 31/0224; H01L 31/0687; H01L 31/18; H01L 31/0725

(52) U.S. Cl. CPC H01L 31/022441; H01L 31/0725; H01L 31/0687; H01L 31/18

(57) ABSTRACT

Multi junction solar cells and methods for making multi junction solar cells are disclosed. Back-contact-only multi junction solar cells having recessed through-substrate vias wherein the side facing the sun, is capable of withstanding environments for use in space are disclosed.

This application is a continuation-in-part of U.S. application Ser. No. 14/213,334 filed on Mar. 14, 2014, which claims the benefit under 35 U.S.C. §119 (e) of U.S. Provisional Application No. 61/794,293 filed on Mar. 15, 2013, and which is a continuation-in-part of U.S. application Ser. No. 13/856,573 filed on Apr. 4, 2013, which claims the benefit under 35 U.S.C. §119 (e) of U.S. Provisional Application No. 61/621,277 filed on Apr. 6, 2012; each of which is incorporated by reference in its entirety.

### FIELD

This disclosure relates to multi junction solar cells and methods for making multi-junction solar cells. More particularly, the disclosure relates to back-contact-only multi junction solar cells having recessed through-substrate vias and the process flows for making such solar cells wherein the side facing the sun, is capable of withstanding environments for both terrestrial and space use.

### BACKGROUND

Because of their high efficiency, conventional multi junction solar cells have been widely used for terrestrial and space applications. Multi junction solar cells include multiple diodes in series connection, known in the art as “junctions,” realized by growing thin regions of epitaxy in stacks on semiconductor substrates. Each junction in a stack is optimized for absorbing a different portion of the solar spectrum, thereby improving efficiency of solar energy conversion.

Conventional multi junction solar cells have features that reduce the efficiency of solar to electrical energy conversion. For example, a portion of solar energy incident on the front side of a solar cell cannot be absorbed due to metallic electrodes blocking a portion of the side facing the sun. Furthermore, a portion of the absorbed solar energy cannot be collected at the electrodes as electrical power because the energy is dissipated as heat (for example, as resistive loss) during lateral conduction in the emitter region of the top junction and in the metallic gridlines. For high-power devices, such as concentrated photovoltaic devices or large area solar cells, the dissipated heat may also result in substantially increased temperature, thereby further reducing the performance of the device. Typically there is a trade-off between these parameters and others. Multi junction solar cells are typically designed to give the optimum solar to electrical energy conversion performance under desired conditions. It is desirable to improve efficiency in multi junction solar cell devices.

Multi junction solar cells can be used in space as well as terrestrially. In addition to the aforementioned design trade-offs, conventional space-qualified multi junction solar cells are also required to exhibit radiation hardness and to have metal interconnect structures integrated with the solar cells. Radiation hardness is defined as minimal degradation in device performance when exposed to ionizing radiation including electrons and protons. For these space-qualified multi junction solar cells, radiation hardness is of great importance for preserving the material quality of the junctions and substrate for an extended lifetime. Typically a space-grade coverglass is used to provide radiation hardness. The space-grade coverglass can be made of several materials including but not limited to borosilicate glass. The application of the coverglass on the cell and the attachment of the interconnect structures require special processing techniques that increase the cost of solar cells used in space. Techniques are, therefore, needed to improve long-term performance of a multi junction solar cell for use in space while considering cost effectiveness, which is facilitated by the ease of production of solar cells with such covers and interconnects.

FIG. 1A shows a cross-section schematic of a typical (prior art) multi junction solar cell device 100. The solar cell 100 shown in FIG. 1A consists of three sub-cells (junctions) 106-108 that are connected through tunnel junctions 167 and 178. It is to be understood that FIG. 1A is merely an example of a typical multi junction solar cell and that such solar cells may include any number of sub-cells. As shown in FIG. 1A, each sub-cell 106/107/108 includes a FSF layer 4, an emitter layer 102, a depletion region 103, a base 104, and a back surface field layer 105. Other suitable sub-cell configurations may be used.

FIG. 1B is a simplified schematic of a typical (prior art) multi junction solar cell device 100.

Referring to FIG. 1A, the front surface field (FSF) region 4 is the window region that faces the sun after cap etch. Underneath the FSF region 4 is the emitter region 102 of the top p-n junction 106 that forms a diode. Similar junctions 107 and 108 are disposed below the top p-n junction thus forming a multi junction solar cell. The top electrode includes gridlines 2 making contact with the FSF region 4 through cap region 3, wherein the cap region 3 consists of semiconductor material patterned according to the shape of the metallic gridlines (metal contacts) 2. The bottom electrode is a metal region 52 at the back surface of the solar cell in contact with the substrate 5. Gridlines 2 and cap region 3 may be covered with a dielectric material 1 such as an anti-reflection coating.

The factors reducing the efficiency of multi junction solar cells, shadowing loss, emitter loss, and grid loss are relevant to the present invention.

Shadowing Loss: In typical multi junction solar cells the top electrode consists of regular grids of metal wires. The metal gridlines 2 and cap regions 3 block sunlight from entering the solar cell. For solar cells for which the width of the cap region is slightly larger than the width of the metal gridlines, the cap width x determines the total width blocking the light for each gridline.

Referring to FIG. 1B, the gridline width x′ is typically related to the cap width x through a process constant x_{c}, such that x=x′+x_{c}. Hence, when the shadowing width x is increased or decreased as a design parameter, the metal width x′ is also increased or decreased by the same amount. For gridlines spaced by a distance y, the shadowing loss is approximately x/y. Therefore, increasing the width x and/or decreasing the spacing y increases the shadowing loss. FIG. 1B includes metal grid lines (metal contacts) 2 on cap regions 3 overlying epitaxial region 45 on substrate 5. A dielectric material 1 overlies metal grid lines 2 and cap regions 3, and the backside of substrate 5 is covered with back metal 52.

Emitter Loss: Carriers are generated across a solar cell as a result of absorption of sunlight. Referring to FIG. 1A, photogenerated carriers that reach the top emitter 102 have to move laterally towards the gridlines 2, as illustrated by arrows 28 in FIG. 2B. The emitter 102 and the FSF 4 are thin, doped semiconductor regions and together form a lateral conduction region 132. Carrier transport across the lateral conduction region 132 results in a resistive power loss that depends on the sheet resistivity of the conductive region and the distance the carriers have to travel to reach the gridlines 2. Hence, for a given sheet resistivity, the smaller the gridline spacing y the smaller the emitter loss is.

Grid Loss: FIG. 2A shows a top view of a solar cell including gridlines 2 having width x with a center-to-center spacing y connected to busbars 22. A detailed view of section 19 is shown in FIG. 2B. FIG. 2B shows the direction of current flow 28 from the active region of a solar cell toward gridlines 2 and current flow 27 along gridlines 2 toward busbar 22. Gridlines are metal resistors, resulting in resistive losses as the current moves toward the busbars 22, as illustrated with arrows 27 in FIG. 2B. The grid loss is determined by the cross-sectional area and the length of the gridlines and the metal resistivity of the gridlines. For larger solar cells the gridlines are longer, resulting in larger [grid loss]/[total loss] ratio compared to smaller solar cells.

The emitter and grid losses are resistive losses (i.e., I²R losses). Hence, when the concentration of incident sunlight increases, the current extracted from the solar cell increases and consequently the I²R losses increase even more. For example, going from a concentration of 500× to 1000× the resistive losses will approximately quadruple for a given cell design.

The grid loss can be made smaller by using more gridlines (hence reducing y) or increasing the cross-sectional area (hence increasing x). Hence, reducing the grid loss (for given process parameters) comes at the expense of increased shadowing loss. In prior art solar cells there is a need to reduce the grid loss component without increasing the shadowing loss component.

The prior art for space-qualified multi junction solar cells includes a product consisting of a solar cell, interconnects, and coverglass (also referred to as CIC). In the fabrication of prior art solar cells, space-qualified coverglass is applied to the front of the solar cell with a transparent adhesive to protect the solar cell from the harsh environment in space. Interconnects for routing power out of the cell are welded onto the front and the back sides of the cell. There is a need for a robust coverglass integration process that is part of the front-end process such that cells can be tested at the wafer-scale after coverglass integration.

Furthermore, the design of a solar cell top electrode and surface affect cover materials or coatings that may be added either on top, surrounding, or on the bottom of the solar cell to protect it from potentially damaging environments, such as environments with high radiation in space. There is a need for a robust coverglass integration process that can be streamlined with the process flow of the solar cell manufacturing.

A through-substrate via (TSV), also known as a through-wafer via (TWV), is an electrical interconnect between the top and bottom surfaces of a semiconductor chip. TSV structures have been routinely used for a variety of applications in the field of semiconductor devices. Fabrication methods to provide TSV structures are known to those skilled in the art of semiconductor devices. For example, Chen et al. (Journal of Vacuum Science and Technology B, Volume 27, Issue 5, “Cu-plated through-wafer vias for AlGaN/GaN high electron mobility transistors on Si”) disclose a semiconductor device with through-wafer vias for a high mobility electron transport device application.

Through-substrate via structures have also been applied to solar cell devices. One of the purposes of using TSV structures in solar cells is to provide a back-contact-only solar cell for packaging requirements. Some approaches for back-contact solar cells have been summarized by Van Kerschaver et al. (Progress in Photovoltaics: Research and Applications 2006; 14:107-123).

Kinoshita et al. (U.S. Application Publication No. 2008/0276981 A1) disclose a structure that provides a through-wafer-via structure incorporating metal with dielectric liner that connects the gridlines on the top surface to the backside of a solar cell. The structure disclosed by Kinoshita provides a back-contact-only solar cell. However the disclosed structure does not reduce grid losses substantially, since gridlines along the length of the cell are used for current transport.

Dill et al. (U.S. Application Publication No. 4,838,952 A) disclose a through-wafer-via structure that connects the emitter region of a solar cell to the backside. The structure disclosed by Dill et al. is not applicable to multi junction solar cells. Multi junction solar cells are comprised of a number of epitaxial semiconductor layers with a variety of doping schemas. Therefore, for multi junction solar cells, it is not possible to use a single doping type around a through-wafer metallic region to electrically isolate it from the semiconductor materials the metallic region is passing through.

Guha et al. (U.S. Pat. No. 8,115,097 B2) disclose a gridline-free contact for a photovoltaic cell. The structure disclosed by Guha et al. employs laterally-insulated through-wafer vias connecting the surface portion of the photovoltaic cell (i.e. the emitter) to the back surface. Contact between the top surface of the metal in the through-wafer via and the emitter region is within the substrate, such that there is a region of semiconductor between the top of the through-wafer via and the top surface of the solar cell. The disclosure by Guha et al. does not teach how though-wafer via structures can be integrated into multi junction solar cells, which employ various thin semiconductor epitaxial layers with different purposes. For example, it is a requirement in multi junction solar cells to use a contact region 3 and a front surface field 4 between the emitter 102 and the metal contact 2.

Therefore, there is a need to increase the efficiency of multi junction solar cells by reducing the grid losses while preventing the solar cell from degradation during use in space.

U.S. Application Publication Nos. 2013/0263920 and 2014/0196779 disclose methods of fabricating solar cells and in particular through-substrate vias for use with solar cells. In these designs, the backside surface of the substrate includes via metal contacts and backside metal. In methods in which both the through-wafer vias and the backside metal are applied during the same processing step, there can be a height difference in the two metallizations. The non-planarity of the backside surface can cause problems with bonding the solar cell wafer to a substrate such as a heat sink.

### SUMMARY

The present invention demonstrates a multi junction solar cell that incorporates several embodiments using at least one through-substrate via formed through the epitaxial region of the solar cell and the substrate to reduce losses associated with metal grid resistance. The epitaxial region includes many epitaxial layers making up the various sub-cells and interfaces between subcells. In particular, through-substrate vias are provided that are electrically isolated from the solar cell substrate and from each of the epitaxial layers overlying the solar cell substrate, except for the cap regions. In addition, the through-substrate vias cross-sectional dimensions are designed to minimize shadowing losses. The multi junction solar cells of the present invention also provide cost-effective coverglass integration that also substantially reduces solar cell degradation for terrestrial and space use. The semiconductor materials used in the substrate may include, for example, gallium arsenide, silicon, and germanium. The epitaxial region may include one or more lattice matched or metamorphic subcells including, for example tunnel junctions, front surface field (FSF), emitter, depletion region, base and back surface field. Semiconductor materials used in these subcells may include, but are not limited to, indium gallium phosphide, indium phosphide, gallium arsenide, aluminum gallium arsenide, indium gallium arsenide, germanium, and dilute nitride compounds such as GaInNAsSb, GaInNAsBi, GaInNAsSbBi, GaNAsSb, GaNAsBi, and GaNAsSbBi. For ternary and quaternary compound semiconductors, a wide range of alloy ratios can be used. The cap regions can be patterned such that they encircle the via structures on the top surface of the solar cell. As a result, gridlines extending across the entire length of the solar cell can be eliminated and electrodes are accessible from the backside of the multi junction solar cell.

In a first aspect, multi junction solar cell devices are provided comprising an element formed in an epitaxial region grown thereon; a plurality of cap regions formed on top of the epitaxial region; a plurality of through-substrate via heads corresponding to each of the plurality of cap regions formed on a back surface of the substrate; through-substrate vias that extend through the substrate from each of the plurality of cap regions to the corresponding through-substrate vias heads; conductive metal within the through-substrate vias and electrically connecting each of the plurality of cap regions to the corresponding through-substrate via heads; an electrically insulating liner disposed on the walls of each of the through-substrate vias insulating the substrate and the epitaxial region from the conductive metal inside the through-substrate vias; an optical cover material disposed upon an optically transparent adhesive material directly above each of the plurality of through-substrate via heads; and a back metal, patterned with a back metal pattern, in ohmic contact with the back surface of the electrically conductive semiconductor substrate, and electrically isolated from the through-substrate via heads.

In a second aspect, methods of forming a through-substrate via heads are provided, comprising providing a substrate having an epitaxial region grown thereon and a plurality of cap regions formed on top of the epitaxial region; depositing a photoresist region on the plurality of cap regions; etching a plurality of through-substrate vias from a backside of the substrate and using the photoresist region as an etch stop layer; depositing an electrically insulating liner within each of the plurality of through-substrate vias; removing the photoresist region to expose the plurality of cap regions; and depositing metal within the through-substrate vias to connect the plurality of cap regions.

In a third aspect, multi junction solar cell devices are provided, comprising a semi-insulating semiconductor substrate having a back surface; an epitaxial region overlying the semi-insulating semiconductor substrate; an electrically conductive semiconductor region between the substrate and the epitaxial region; at least one multi junction solar cell element formed in the epitaxial region, the epitaxial region being grown on the electrically conductive semiconductor region; a cap region overlying the epitaxial region; though-wafer vias that extend from the cap region to the back surface of the substrate; the cap region being shaped according to a cap pattern including collars around the through-wafer vias; conductive metal within the through-wafer vias and electrically connected to the cap patterned collars; an electrically insulating liner on the walls of the through-wafer vias insulating the conductive metal inside the through-wafer vias from at least the epitaxial region and from the conductive semiconductor region; an optical cover material disposed upon an optically transparent adhesive material directly above the through-substrate via heads formed on top of the epitaxial region; and a back metal on the back surface of the substrate in electrical contact with the conductive metal in the through-wafer vias.

In a fourth aspect, multi junction solar cell devices are provided, comprising an electrically conductive semiconductor substrate with at least one multi junction solar cell element formed in an epitaxial region grown thereon; a plurality of cap regions formed on top of the epitaxial region; through-substrate vias that extend from the plurality of cap regions to a back surface of the substrate; conductive metal within the through-substrate vias and electrically connected to the plurality of cap regions; an electrically insulating liner disposed on the walls of the through-substrate vias insulating the substrate and the epitaxial region from the conductive metal inside the through-wafer vias; a through-substrate via head that electrically connects the conductive metal within the through-substrate vias with the plurality of cap regions, henceforth called; a temporary carrier substrate bonded directly above the through-substrate via heads formed on top of the epitaxial region; and a back metal, patterned with a back metal pattern, in ohmic contact with the back surface of the electrically conductive semiconductor substrate, and electrically isolated from the conductive metal within the through-substrate vias.

In a sixth aspect, methods of forming a multi junction solar cell devices are provided, comprising providing an electrically conductive semiconductor substrate with at least one multi-junction solar cell element formed in an epitaxial region grown thereon, and a plurality of cap regions formed on top of the epitaxial region; bonding a cover glass on top of the substrate and the plurality of cap regions; thinning the substrate; etching through-substrate vias from a back surface of the substrate; forming a patterned dielectric layer on the back surface of the substrate; and forming electrical connection between the patterned cap region and the back metal contacts pads with conductive metal inside the through-substrate vias, such that the contact pads are not directly electrically connected to the semiconductor substrate.

In a seventh aspect, methods of forming a multi junction solar cell devices are provided, comprising providing an electrically conductive semiconductor substrate with at least one multi junction solar cell element formed in an epitaxial region grown thereon, and a patterned cap region formed on top of the epitaxial region; bonding a polymer cover on top of the substrate and the patterned cap region; thinning the substrate; etching through-substrate vias from a back surface of the substrate; forming a patterned dielectric layer on the back surface of the substrate; forming a plurality of back metal contact pads; and forming electrical connection between the patterned cap region and the back metal contacts pads with conductive metal inside the through-substrate vias, such that the contact pads are not directly electrically connected to the semiconductor substrate.

In another aspect, multi junction solar cells are disclosed, comprising: an electrically conductive semiconductor substrate with at least one multi junction solar cell element formed in an epitaxial region grown thereon; an annular cap region formed on top of the epitaxial region; through-substrate vias that extend from the annular cap region to a back surface of the substrate; conductive metal within the through-substrate vias and electrically connected to the annular cap region; an electrically insulating liner disposed on the walls of the through-substrate vias insulating the substrate and the epitaxial region from the conductive metal inside the through-wafer vias; a through-substrate via head that electrically connects the conductive metal within the through-substrate vias with the annular cap region, henceforth called; and a back metal, patterned with a back metal pattern, in ohmic contact with the back surface of the electrically conductive semiconductor substrate, and electrically isolated from the conductive metal within the through-substrate vias.

In another aspect, multi junction solar cells are disclosed, comprising: a semi-insulating semiconductor substrate having a back surface; an epitaxial region overlying the semi-insulating semiconductor substrate; an electrically conductive semiconductor region between the substrate and the epitaxial region; at least one multi junction solar cell element formed in the epitaxial region, the epitaxial region being grown on the electrically conductive semiconductor region; a cap region overlying the epitaxial region; though-wafer vias that extend from the cap region to the back surface of the substrate; the cap region being shaped according to a cap pattern including collars around the through-wafer vias; conductive metal within the through-wafer vias and electrically connected to the collars; an electrically insulating liner on the walls of the through-wafer vias insulating the conductive metal inside the through-wafer vias from at least the epitaxial region and from the conductive semiconductor region; and a back metal on the back surface of the substrate in electrical contact with the conductive metal in the through-wafer vias.

In another aspect, methods of making multi junction solar cells incorporating an optical cover material during the process flow and having through-substrate vias such as those in the first and second aspects are disclosed. Such process flows for incorporating a through-substrate via in the multi junction solar cell are efficient and cost effective and use an optical cover glass as a carrier substrate during backside processing. The cover glass is also designed to then withstand reliability conditions for solar cell use, and in some cases, for use in space. In particular, the process flows disclose backside etching of the through-substrate vias once the epitaxial wafer, on the front side, is already processed.

In another aspect, multi junction solar cell devices are provided, comprising a substrate comprising a front side surface and a backside surface; an epitaxial region overlying the substrate, wherein the epitaxial region comprises at least one multi junction solar cell; a plurality of cap regions overlying the epitaxial region; a metal region overlying each of the plurality of cap regions; a plurality of recesses within the backside surface of the substrate, wherein each of the plurality of recesses corresponds to one of the metal regions; a through-substrate via extending through the epitaxial region and the substrate from the metal region to the corresponding recess; an electrically insulating liner disposed on the sidewalls of each of the through-substrate vias and within the corresponding recess; a via metal contact corresponding to each of the through-substrate vias; a backside metal on the backside substrate surface; an insulating region between each of the via metal contacts and the backside metal; an electrically conductive metal within each of the through-substrate vias electrically connecting each of the plurality of cap regions with the corresponding via metal contact; wherein the via metal contacts and the backside metal layer form a substantially planar surface.

In another aspect, methods of forming a multi junction solar cell devices are provided, comprising providing an electrically conductive semiconductor substrate comprising: a topside surface and a backside surface; an epitaxial region overlying the substrate, wherein the epitaxial region comprises at least one multi junction solar cell; a plurality of cap regions overlying the epitaxial region; and a metal region overlying each of the cap regions; providing a plurality of recesses in the backside surface of the substrate, wherein each of the plurality of recesses corresponds to one of the plurality of cap regions; etching through-substrate vias extending from each of the plurality of recesses to the corresponding cap region; providing an insulating liner within the sidewalls of each of the plurality of through-substrate vias and within each of the recesses; providing an electrically conductive metal within each of the through-substrate vias; and providing via metal contacts and a backside metal to provide a metallized backside surface; wherein the metallized backside surface is substantially planar.

In the following description, reference is made to the accompanying drawings which form a part hereof wherein like numerals designate like parts throughout, and in which is shown by way of illustration specific embodiments in which the invention may be practiced.

### BRIEF DESCRIPTION OF THE DRAWINGS

The drawings described herein are for illustration purposes only. The drawings are not intended to limit the scope of the present disclosure.

FIG. 1A is a cross-sectional diagram of a multi junction solar cell in which the invention may be used.

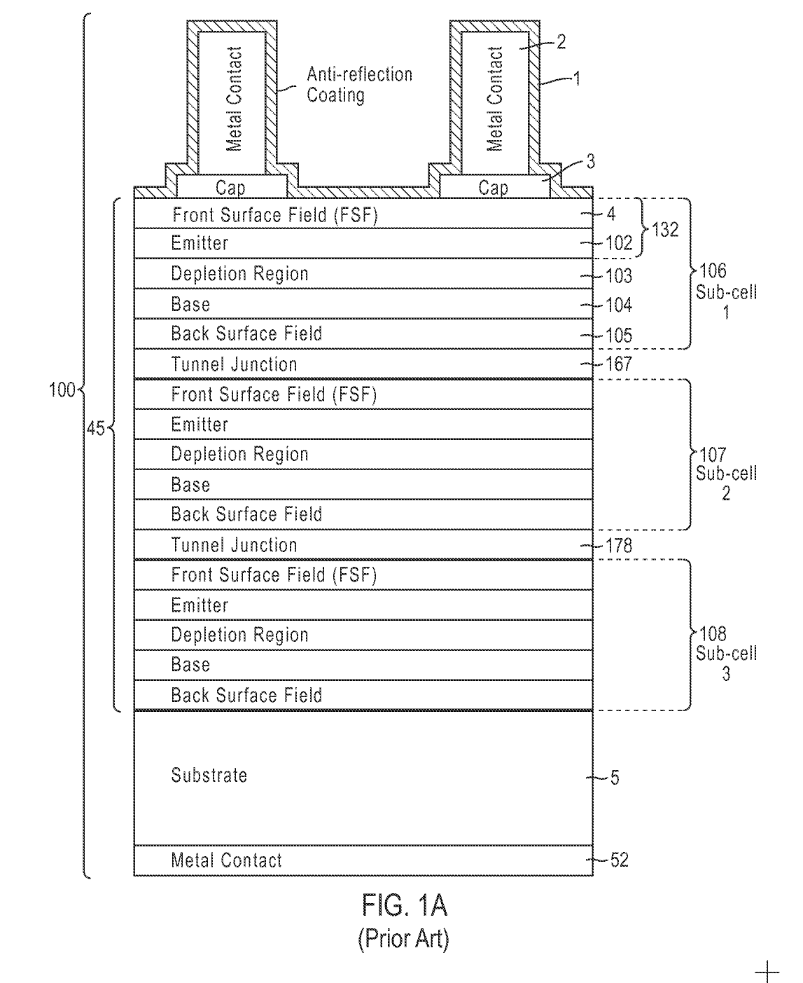

FIG. 1B is a simplified version of FIG. 1A.

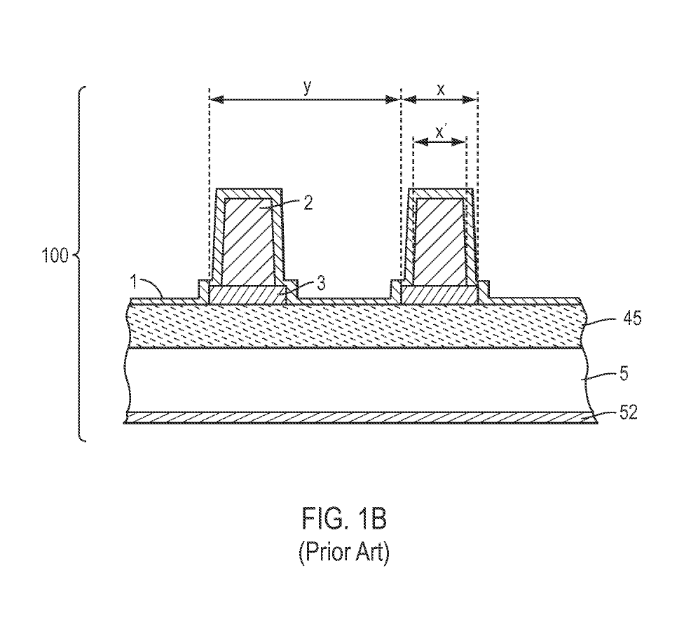

FIG. 2A shows a typical prior art solar cell with gridlines 2 and busbars 22.

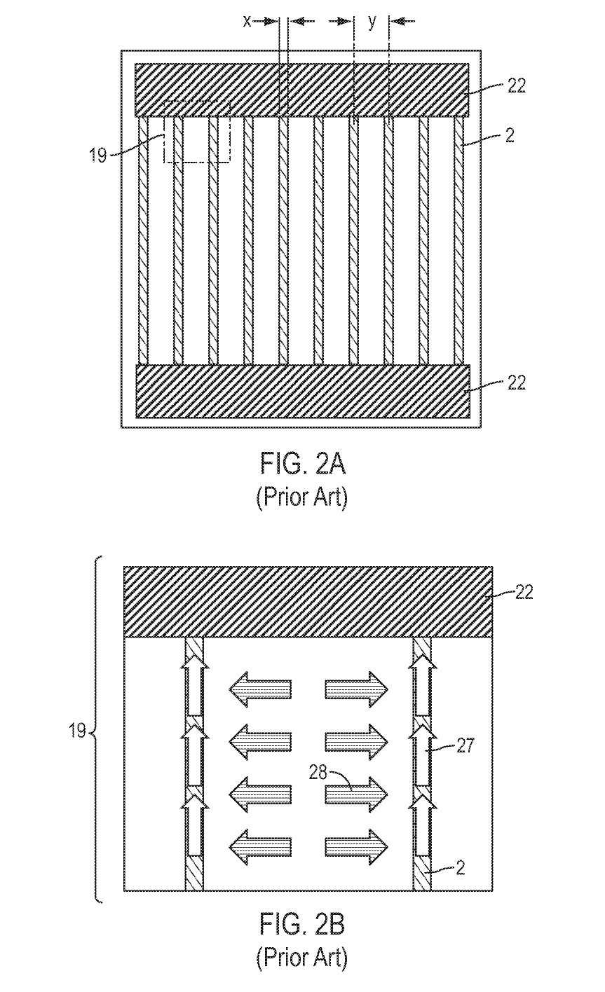

FIG. 2B shows where the grid losses and emitter losses occur.

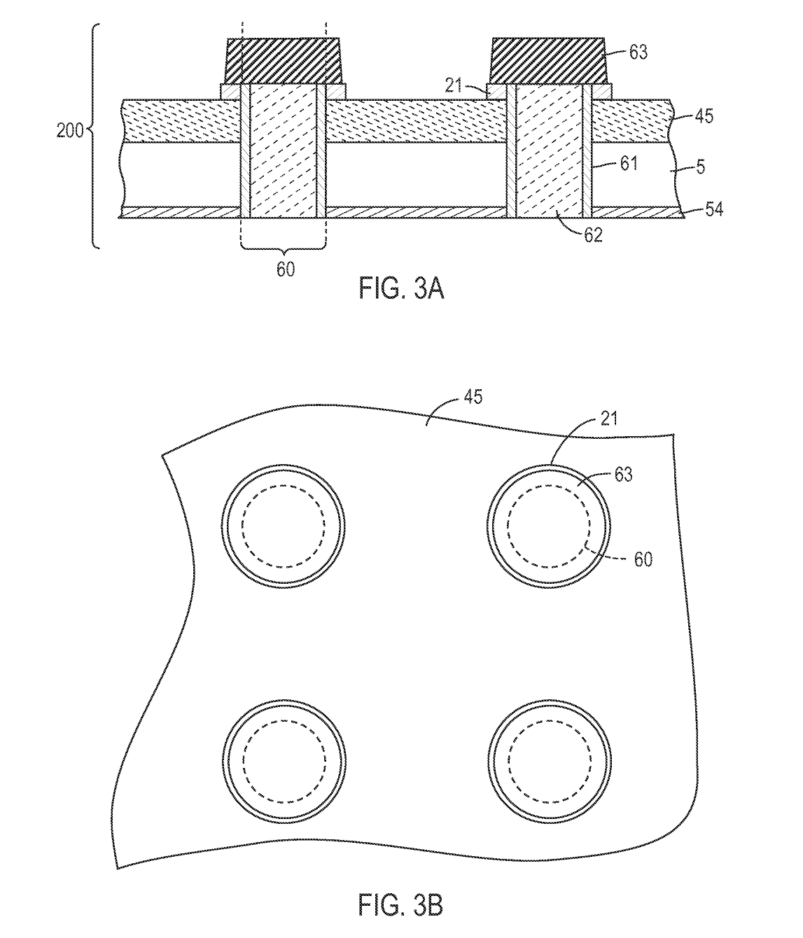

FIG. 3A shows an embodiment provided by the present disclosure.

FIG. 3B shows a top view of the apparatus shown in FIG. 3A.

FIG. 4A shows an embodiment provided by the present disclosure.

FIG. 4B shows a top view of FIG. 4A.

FIG. 5A shows an embodiment provided by the present disclosure.

FIG. 5B shows a top view of the apparatus shown in FIG. 5A.

FIG. 5C shows a backside view of the apparatus shown in FIG. 5A.

FIG. 6A shows an embodiment provided by the present disclosure.

FIG. 6B shows a cross-sectional diagram of the apparatus shown in FIG. 6A.

FIGS. 7A-7F illustrate a process flow for certain embodiments provided by the present disclosure.

FIGS. 8A-8F illustrate a process flow for certain embodiments provided by the present disclosure.

FIG. 9A-9F illustrate a process flow for certain embodiments provided by the present disclosure.

FIG. 10A-10I illustrate a process flow for certain embodiments provided by the present disclosure.

FIG. 11 shows a top view of the apparatus shown in FIG. 10I.

Reference is now made in detail to embodiments of the present disclosure. While certain embodiments of the present disclosure are described, it will be understood that it is not intended to limit the embodiments of the present disclosure to the disclosed embodiments. To the contrary, reference to embodiments of the present disclosure is intended to cover alternatives, modifications, and equivalents as may be included within the spirit and scope of the embodiments of the present disclosure as defined by the appended claims.

### DETAILED DESCRIPTION

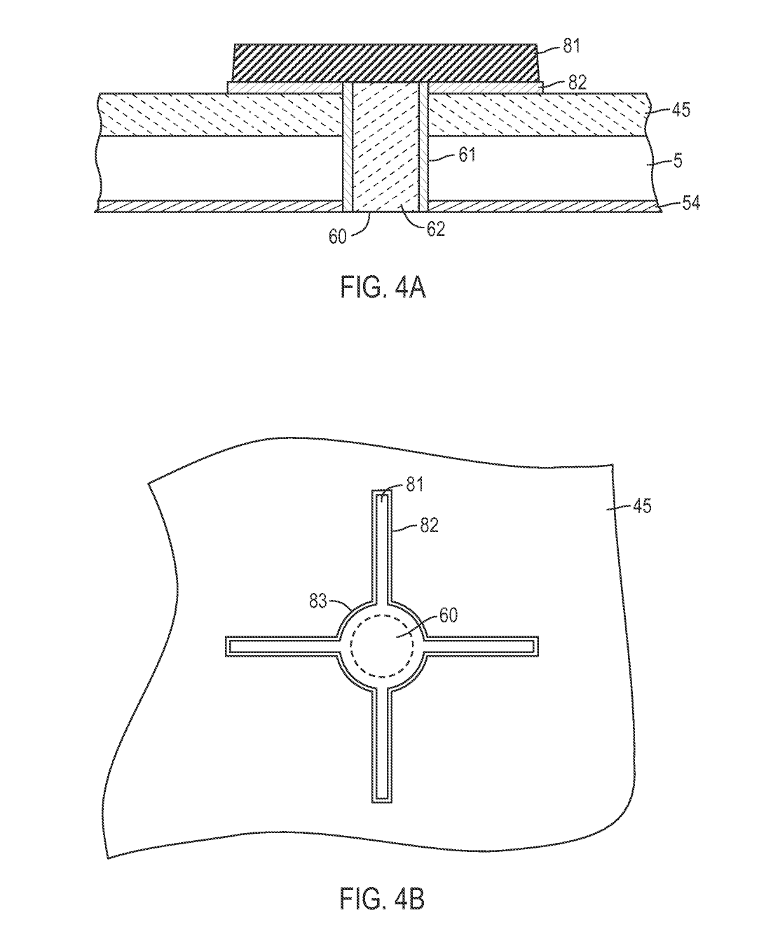

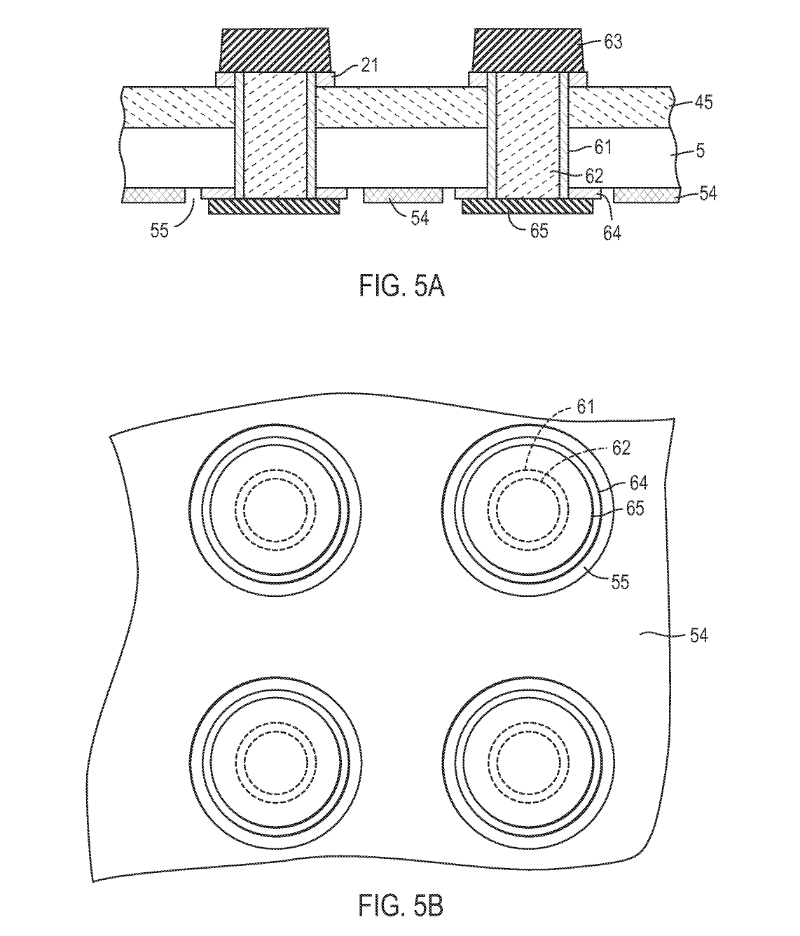

In one embodiment of the invention, shown by FIGS. 3A and 3B, the solar cell 200 with one or more subcells forming the epitaxial region 45, has an annular cap region 21 formed on top of the epitaxial region 45. A metal region 63 on top of the annular cap 21 makes ohmic contact with the annular cap 21. The metal region 63 on top of the annular cap 21 is also referred to as “the through-substrate via head”. FIG. 3A also shows substrate 5, epitaxial region 45, back metal 54, and via 60, which includes via metal 62 and insulating liner 61. FIG. 3B shows a top plan view of the solar cell of FIG. 3A including annular cap 21, metal region 63, via 60, and front surface of epitaxial region 45.

In certain embodiments, the center-to-center distance between adjacent through-substrate vias is from about 100 μm to about 200 μm, from about 100 μm to about 150 μm, from about 150 μm to about 200 μm, and in certain embodiments, from about 125 μm to about 175 μm. In some embodiments, the center-to-center distance between adjacent through-substrate vias is approximately 60 μm and up to 1 mm or larger. The vias may be arranged in an appropriate configuration to optimize the performance of the solar cell.

It is an objective of certain embodiments to reduce the number of vias in the solar cell, for a given cell size, by placing them further apart from each other in order to reduce shadowing loss. The present embodiment keeps the emitter loss small enough by use of metallic wires extending out from the via regions, such that the lateral distance current flows through the lateral conduction layer is not substantially increased. Since the metallic wires can be made much shorter compared to typical prior art gridlines, the resistive losses associated with them will be minimal. The metallic wires can follow a variety of patterns depending on the multi-junction solar cell design requirements. Since the metallic wires are typically short, it may not be necessary to use silver or other high conductive metals to make the metallic wires. Hence the present embodiment enables multi junction solar cells without silver metallization. Metallization that does not use silver may be advantageous for production and manufacturing. For example, silver is typically not allowed on production equipment sets that are used for making other products that do not contain silver. Therefore, the cost effective elimination of silver from the device may enable benefits for manufacturing the multi junction solar cell device.

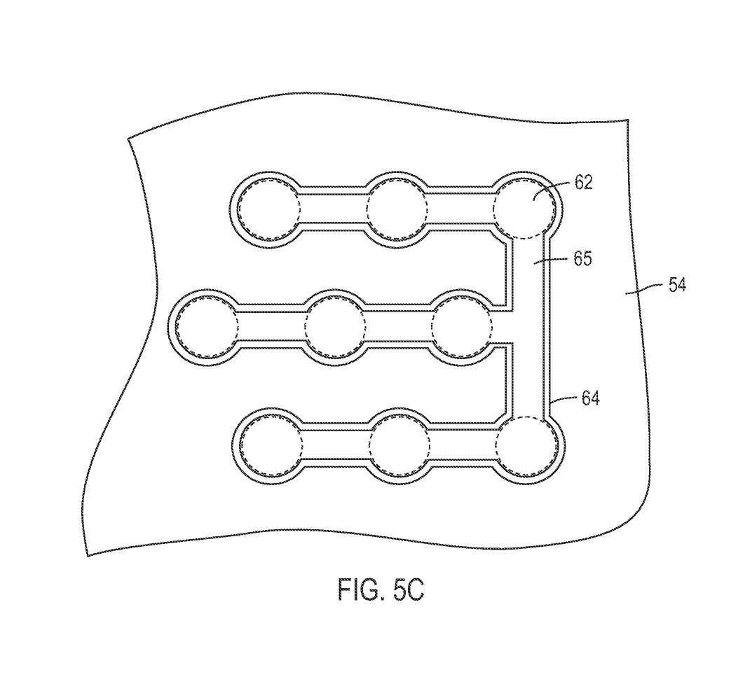

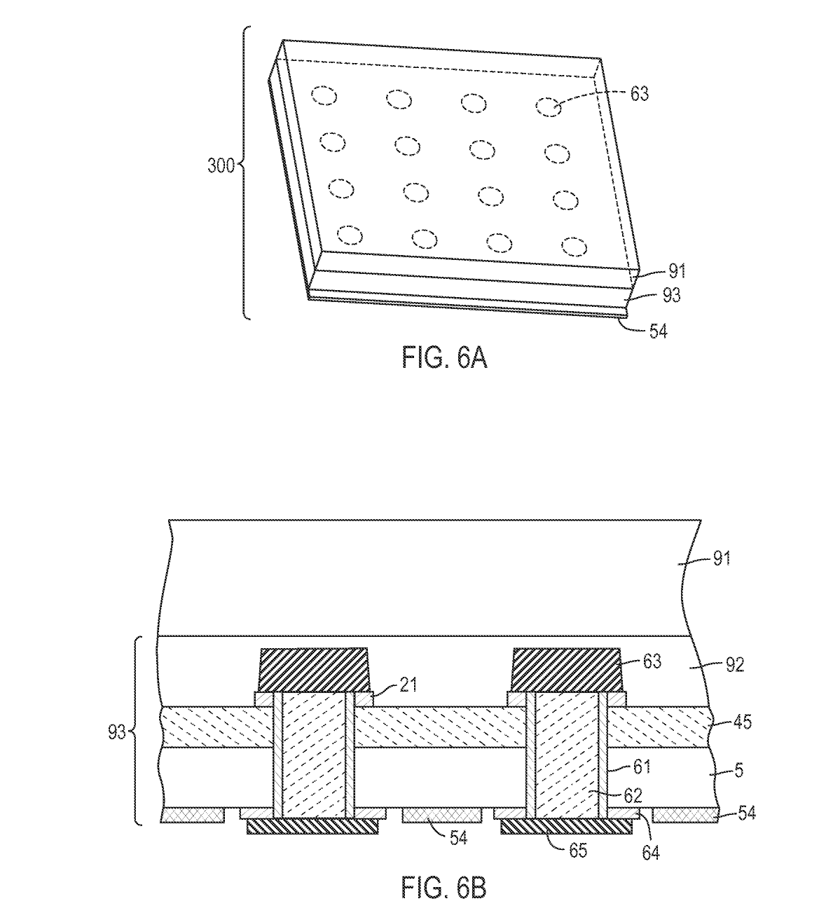

In some embodiments, as shown in FIGS. 4A and 4B, narrow metal gridlines 81 on the front side of a solar cell may be provided extending from the through-substrate via head region 83 along narrow cap regions 82 on top of the epitaxial region 45. A through-substrate via 60 extends from the annular cap region 83 to the backside of the substrate 5. A via metal 62 within the through-substrate via 60 extends from the annular cap to the backside of the substrate 5 in the inner region of the through-substrate via. In some embodiments, this via metal may include gold or copper. In some embodiments a via metal does not fill the entire via. FIG. 4B is a planar view of the upper surface of the device shown in FIG. 4A, and includes narrow metal gridlines 81 overlying the narrow cap regions 82 disposed over through via 60 and epitaxial region 45.

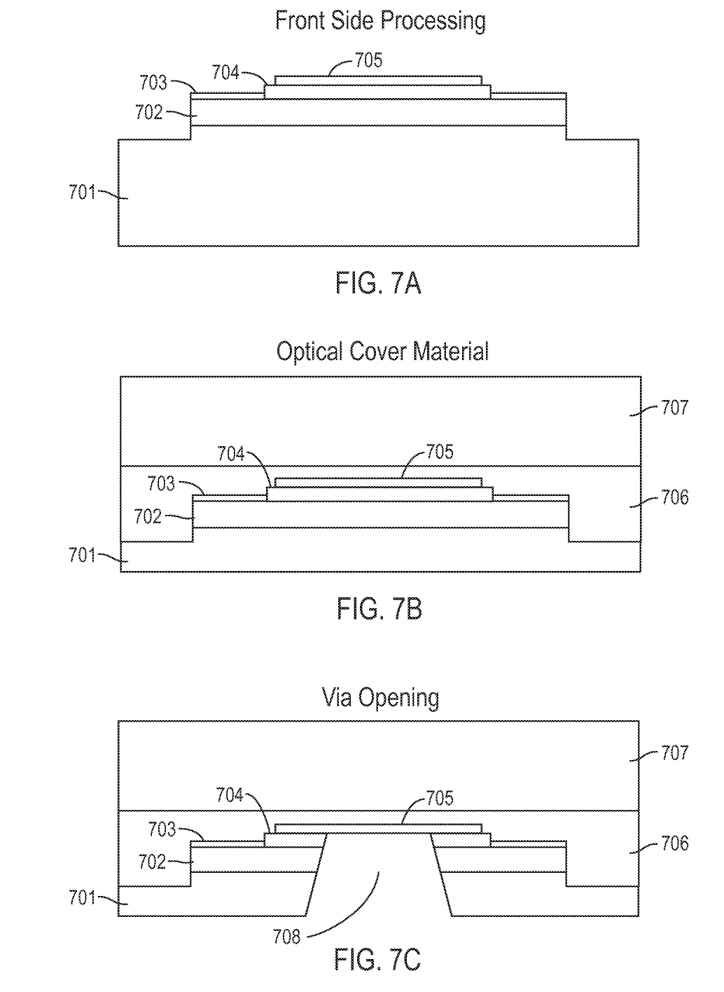

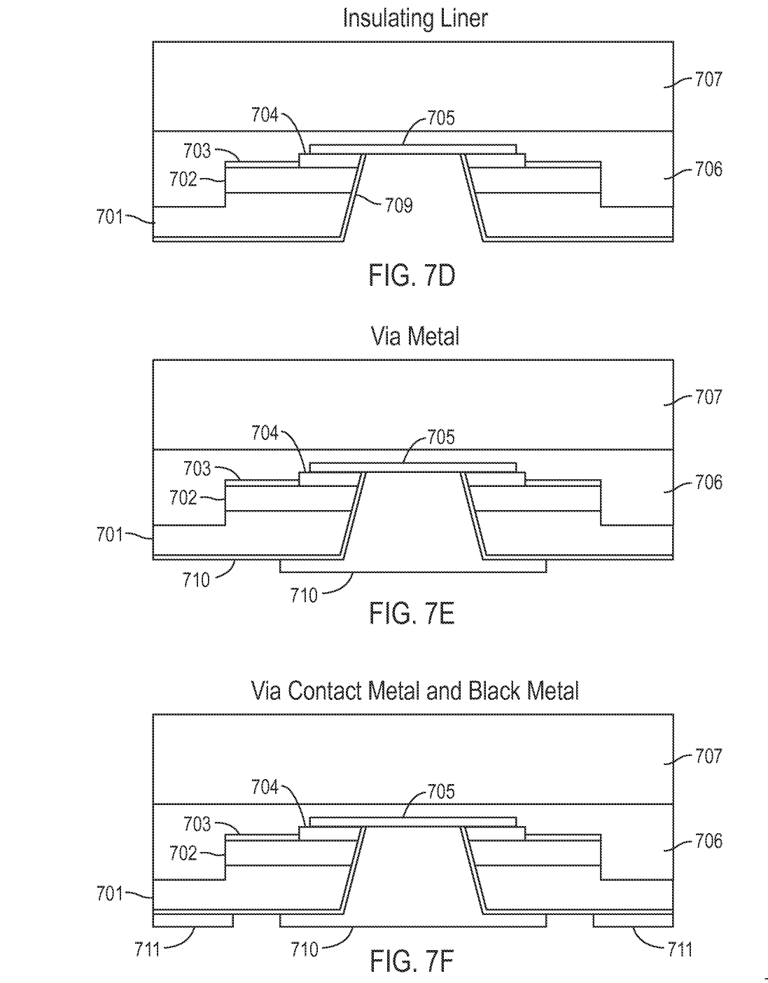

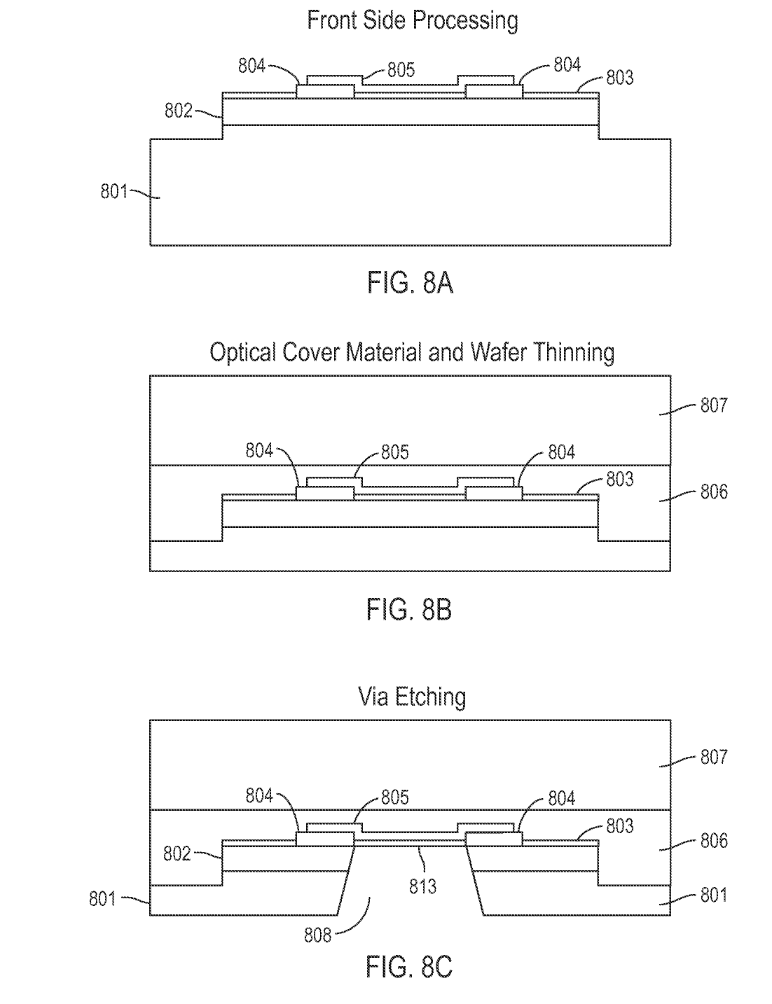

As shown in FIG. 4A, an electrically insulating layer 61 lines the walls of the through-substrate via around the conductive metal, thereby electrically insulating the substrate 5 and the epitaxial region 45 from the via metal 62 inside the through-substrate vias 60. In some embodiments, this insulating layer may be a dielectric such as silicon dioxide or silicon nitride. In other embodiments, the insulating layer may be a polymer. The insulating layer 61 is patterned inside the via so that the via metal 62 makes ohmic contact with the through-substrate via head 81. In some embodiments, an insulating layer 61 such as a polymeric material is patterned inside the via by a self-patterning process using selective deposition. In some embodiments, as shown in FIG. 5A, the insulating layer 61 conformally covers a portion 64 of the backside of the substrate in addition to the inside of the vias, such that the insulating layer on the backside of the substrate is patterned in a back contact pattern, resulting in a patterned insulating layer on the backside. In other embodiments, the patterned insulating layer on the backside may be applied and patterned separately from the insulating layer inside the vias. Back metal 54, which may include back contact pads, may be applied on the backside of the substrate outside of the areas occupied by the patterned insulating layer 64 on the backside of the substrate such that the back metal 54 makes ohmic contact with the substrate 5. In some embodiments, as shown in FIGS. 5A and 5B, there is a space or gap 55 between patterned insulating layer 64 and back side metal contact 54. In some embodiments the back metal may include gold, titanium, and/or platinum.

Referring to FIGS. 5A and 5B, via contact metal regions 65, which may include via contact pads, may be attached to the patterned insulating layer 64 on the backside of the substrate such that the via contact metal regions 65 are in direct electrical contact with the via metal 62 but not electrically connected directly to the semiconductor substrate 5 or to the back metal 54. In some embodiments, contact metal regions 65 may include gold, titanium, platinum, and/or copper.

In some embodiments, as shown in FIG. 5C, the patterned insulating layer 64 on the backside and the via contact metal regions 65 are patterned such that multiple via metal contact regions 65 are electrically connected. In some embodiments, the via contact metal regions 65 and the back metal are patterned in a complementary pattern, henceforth referred to as an inter-digitating back contact pattern.

In some embodiments, a device contains no silver metal; that is, the narrow gridlines along the cap, the via head metal, the via metal, the via contact metal region, and the back metal do not contain silver.

In some embodiments, the cap regions and the vias can have other shape factors such as rectangles, squares, or other shapes not limited to the annular shape. Such shapes may include cap regions which form a closed circular, rectangular or other shape around the entire perimeter of the via hole. Or, such cap regions may not surround the entire perimeter of the via hole.

In another embodiment, the through-substrate via head structures are covered with an optically transparent material with smooth edges.

In other embodiments, the through-substrate via head forms a planar metal region.

In other embodiments, the via metal directly connects to the annular cap region such that the through-substrate via head and the via metal are formed in a single process step.

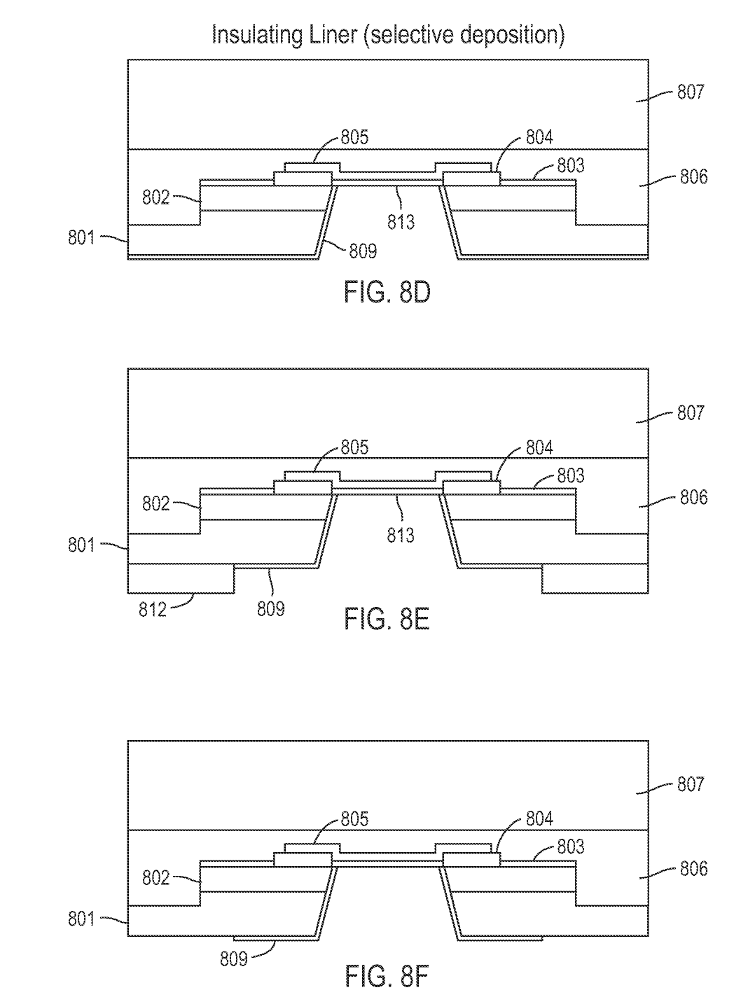

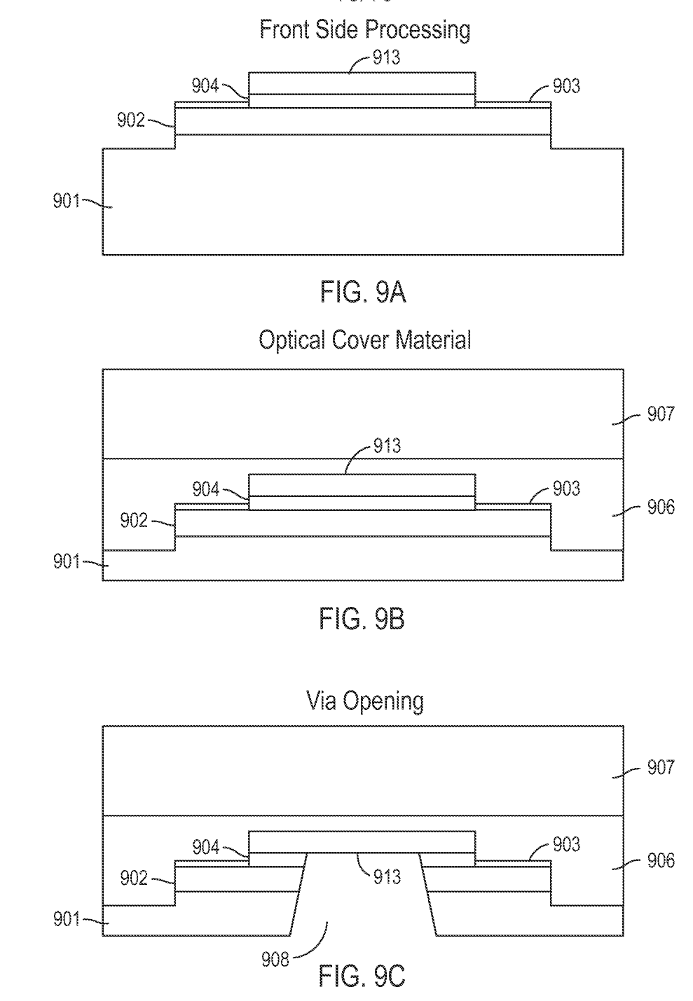

Referring to FIGS. 6A and 6B, in some embodiments, an optical cover material 91 is bonded permanently to the top side of a solar cell 93 using a planarizing optical adhesive (not shown), such that no electrical connection is available from the top surface of the solar cell 300. In some embodiments, this optical cover material 91 is a space-grade coverglass, which may be made of a variety of space-grade materials, including but not limited to, borosilicate glass. In some embodiments, the optical cover glass may incorporate dome shapes and be made of a polymer material. In some embodiments, this optical cover material is bonded permanently at the wafer-scale prior to substrate thinning, a process well known to those skilled in the art, and used also as a carrier substrate during substrate thinning and subsequent process steps on the substrate backside. FIG. 6B shows optical cover material 91, adhesive 92, metal contact region, annular cap region 21, epitaxial region 45, substrate 5, insulating liner 61, via metal 62, via contact metal regions 65, and backside metal 54.

In some embodiments, for example, a carrier substrate is bonded temporarily at the wafer-scale prior to substrate thinning, a process well known to those skilled in the art, and used to provide mechanical support during subsequent process steps. This temporary carrier is removed from the final multi junction device and serves as a mechanical support for the epitaxial layers during processing. In some embodiments, the carrier substrate may be a cover glass or other material.

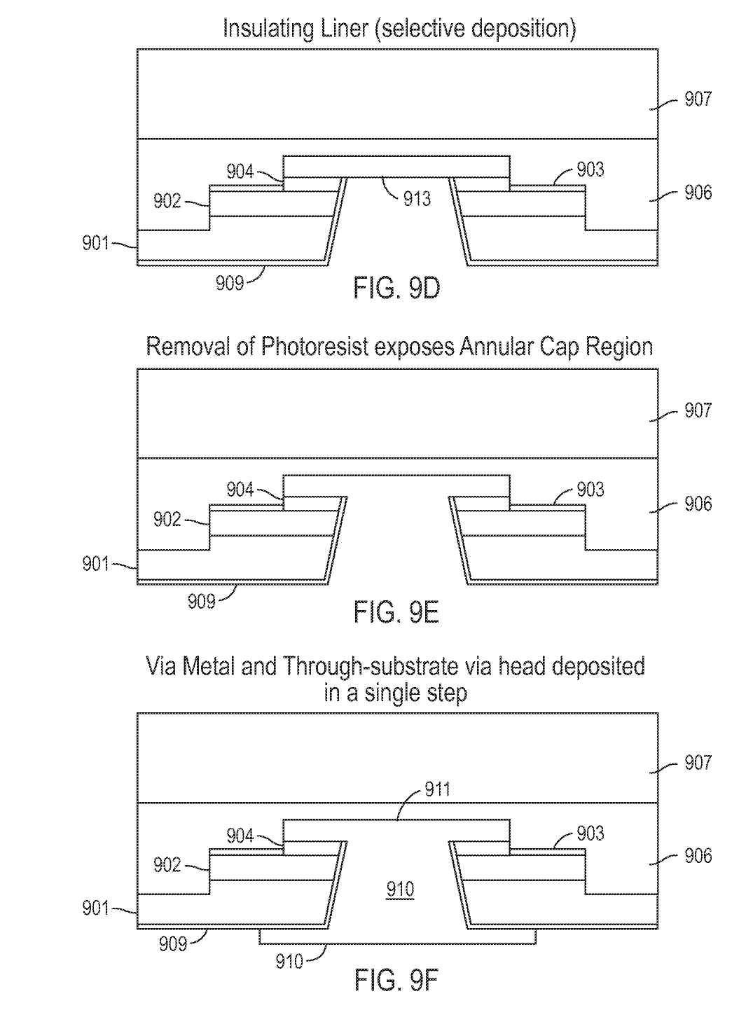

In the embodiments comprising an optical cover material, which may be a space-grade coverglass, as illustrated in FIGS. 7A-7F, the following process modules may be used for cost-effective process integration.

1. (FIG. 7A) Front side processing is done using semiconductor processing techniques to form annular cap regions 704 and the through-substrate via heads 705 on the front side of the solar cells. The annular cap region 704 may be patterned in a disk shape at this process step. Through-substrate via heads 705 may be smoothly applied on top of the disk-shaped cap regions 704. The narrow metal gridlines (not shown) may also be formed during front side processing. In some embodiments, anti-reflection coating 703 may be applied over epitaxial layer 702 at this process step. Epitaxial layer 702 overlies substrate 701. At the end of this process module a wafer with front side processing is obtained.

2. (FIG. 7B) The wafer with front side processing is bonded permanently to an optical cover material 707 using a planarizing adhesive 706. In some embodiments, the optical cover material 707 may be space grade coverglass which may be made of borosilicate glass.

3. The substrate 701 is thinned after being bonded to the optical cover material 707. The thickness of the substrate after substrate thinning can range between 0.1 μm and 200 μm.

4. (FIG. 7C) The backside of the substrate is patterned with photoresist or suitable masking material in a through-wafer-via pattern. The through-substrate vias 708 are etched from the backside of the substrate 701 such that the etch stops on the through-substrate via heads 705, which act as a selective etch stop layer. As a result of the via etch, annular cap regions 704 are formed in place of the disk-shaped cap regions. The patterned photoresist is removed after the patterning is done.

5. (FIG. 7D) An insulating liner 709 is applied over the substrate backside. The insulating layer can be applied using standard deposition techniques, including but not limited to, plasma-enhanced chemical vapor deposition, atomic layer deposition, or electrografting.
Using standard photolithography techniques, the insulating liner 709 is patterned so that the through-substrate via heads 705 are exposed. The patterned insulating layer on the backside may also be formed at this step.

6. (FIG. 7E) Via metal 710 is applied inside the vias such that the via metal 710 makes electrical connection to the through-substrate via heads 705.

7. (FIG. 7F) Via contact metal regions 712 and back metal 711 are applied. In some embodiments, these two metals can be applied in a single deposition step.

FIGS. 7A-7F include the following elements: substrate 701, epitaxial layer 702, dielectric material 703, disk-shaped or annular cap regions 704, through-substrate via head 705, planarizing adhesive 706, optical cover material 707, via 708, insulating liner 709, via metal 710, back metal 711, and via contact metal regions 712.

The process flow described herein is merely an example and other process flows with different steps can be used to achieve optical-cover material integrated wafer-level processing to realize through-substrate via solar cells. Using such an integrated process flow eliminates several steps and provides substantial cost savings.

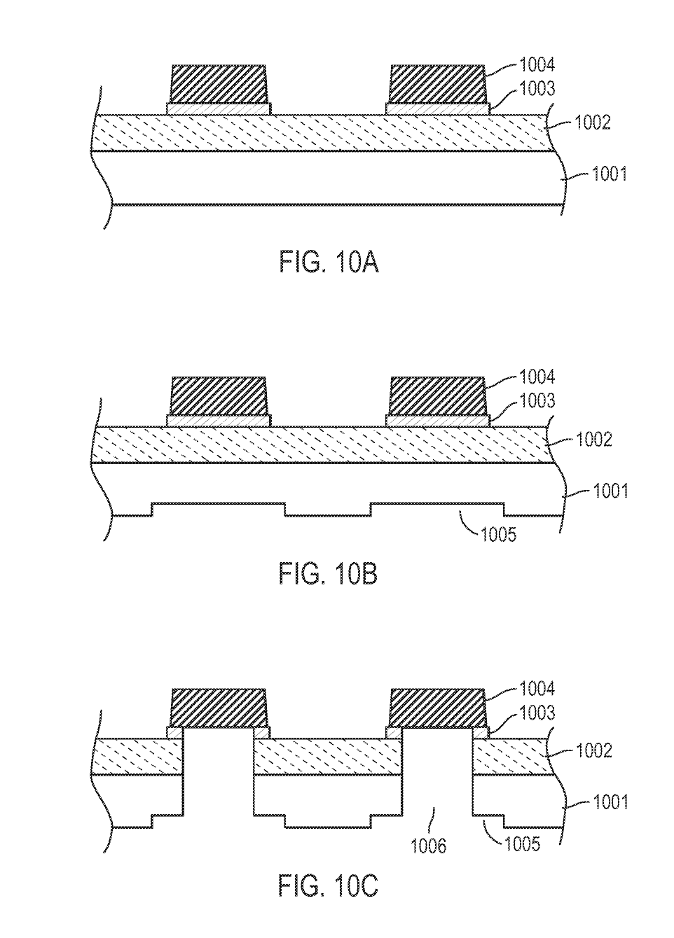

FIGS. 8A-8F include the following elements: substrate 801, epitaxial region 802, dielectric material 803, dielectric material inside the via 813, annular cap region 804, through-substrate via head 805, planarizing adhesive 806, optical cover material 807, via 808, insulating liner 809, via metal 810, and patterned photoresist 812.

In another embodiment of the above-described device, as shown in FIGS. 8A-8F, during a front side processing step, the cap region 804 is patterned in an annular shape and a dielectric material 803 is deposited inside and around the annular cap region 804. In some embodiments, the dielectric material 803 inside the annular cap region 804 may be antireflection coating. A through-substrate via head 805 is applied such that it makes contact with the top side of the annular cap region 804 and the top side of the dielectric material 803 inside the annular cap region 804.

FIG. 8B shows a wafer after an optical cover 807 is applied to the front side surface of the device using a planarizing adhesive 806.

At the via etching step (FIG. 8C), the via etching stops at the dielectric material 813 inside the annular cap region 804 instead of the through-substrate via head 805, wherein the dielectric material acts as an etch stop layer during etching of the through-substrate vias 808.

In an embodiment, at the insulating liner application step (FIG. 8D), a selective deposition technology can be used such that insulating liner 809, which may be a polymer, is deposited only on conductive and semi-conductive surfaces and is not deposited on insulating surfaces, including but not limited to dielectrics (e.g., antireflection coatings) and polymers (e.g. photoresist). Using such a selective deposition technology the insulating liner covers the via sidewalls and the backside of the substrate, but not the dielectric inside the annular cap region.

In some embodiments, as shown in FIG. 8E, a photoresist pattern 812 may be used on the backside of the substrate, preventing deposition of the selectively-deposited insulating liner on parts of the backside protected by the photoresist. The photoresist is removed after the deposition of the insulating liner is completed. In some embodiments, electrografting technique can be used to deposit the insulating liner selectively or non-selectively. Subsequently, as shown in FIG. 8F, dielectric material inside the cap region is removed prior to via metal deposition, which may include in some embodiments selective wet etching of the dielectric (e.g., antireflection coating) that does not etch the insulating polymer on the via sidewalls. The selective deposition technology may allow for achieving small via diameters and may eliminate additional photolithography steps during the process.

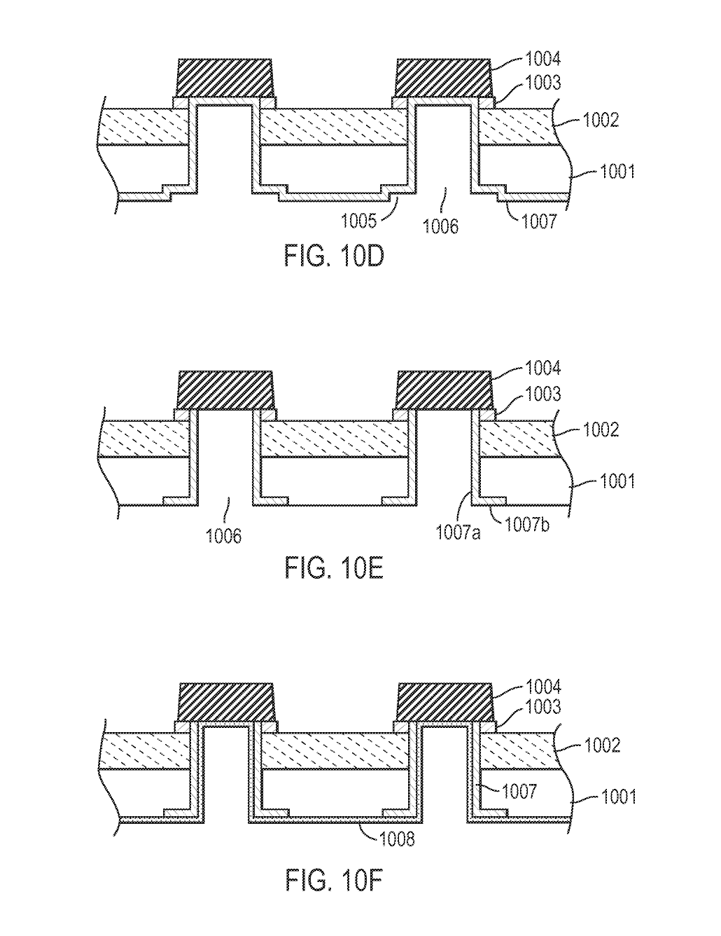

In another embodiment of the above-described process, as shown in FIGS. 9A-9F, through-substrate via heads may be formed by a process flow integrating via metal deposition and through-substrate via head deposition. FIGS. 9A-9F include the following elements: substrate 901, epitaxial region 902, dielectric material 903, disk-shaped or annular cap region 904, photoresist region 913, planarizing adhesive 906, optical cover material 907, via 908, insulating liner 909, via metal 910, and through substrate via head 911.

In this process flow a photoresist region 913 is deposited on the disk-shaped cap region 904 (FIG. 9A). This photoresist region 913 is used as an etch stop layer when the through-substrate vias are etched from the backside of the substrate (FIG. 9C). Subsequently insulating liner is applied and patterned (FIG. 9D). The selective deposition technology may also be used since photoresist is an insulator. Subsequently the photoresist region may be removed using standard semiconductor processing steps and the annular cap region is thus exposed (FIG. 9E). Finally, a via metal 910 and through-substrate via head may be deposited in a single deposition step such that the through-substrate via head makes ohmic contact with the annular cap region (FIG. 9F).

In certain embodiments, a through-substrate via may include a recess on the backside surface of the substrate. Bonding the wafer containing the solar cells to a substrate such as a thermal heat sink is facilitated when the backside surface of the solar cell is planar. As shown, for example in FIG. 5A, in certain of the disclosed methods, the via metal pads 65 and the backside contact pads 54 extend to different heights above the surface of substrate 5 thereby producing a non-planar surface. In methods in which both the through-wafer via and the backside metal contacts are formed during the same processing step, there can be a step height difference due to the presence of the insulating liner 64. The step height difference can be equal to the thickness of the insulating liner 64 that separates the via metal pads 65 from the substrate 5. Depending in part on the composition of the insulating liner, certain insulting liners can be sufficiently thick that the height differences between the various regions of the backside surface can complicate bonding the backside to a substrate such as to a heat sink or other surface associated with a solar cell package. Therefore, it is desirable to use a processing method that provides a substantially planar backside surface.

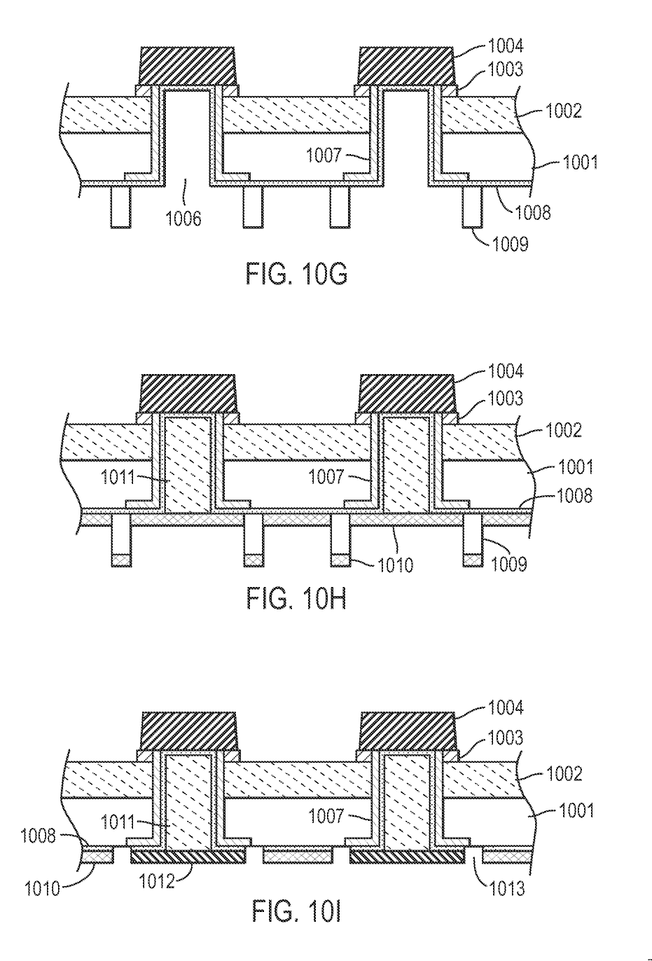

An example of process steps for providing a planar backside surface are shown in FIGS. 10A-10I.

FIG. 10A shows a cross-section of a wafer following front side processing including semiconductor substrate 1001, epitaxial region 1002, disk-shaped cap region 1003 and metal region 1004 overlying respective cap regions.

As shown in FIG. 10B, recesses 1005 are photolithographically defined on the backside surface of the substrate and etched to a depth similar or equal to the thickness of the insulating liner.

As shown in FIG. 10C, via holes 1006 are photolithographically defined and etched through the substrate 1001, epitaxial region 1002, and cap region 1003.

Next, as shown in FIG. 10D, an insulating liner is deposited within vias 1006 and within the recess region 1005 and on the backside surface of the substrate 1001. The insulating liner 1007 is deposited by electroplating and because it is a self-limiting process the thickness of the insulating liner can be controlled. For example, the insulating liner thickness can be from about 3 μm to about μm. Controlling the thickness of the insulating liner can be important because the dimensions of the via hole may not be uniform. Depositing a known thickness of the insulating liner can ensure a sufficient thickness to prevent failure during device operation. In embodiments in which the insulating liner is an electrografted polymer or an oxide, an extra lithography and etch-back step will be needed to define the backside contact pattern and to open the deposited liner in regions where connection to the through-substrate via head 1004 will be made. However, by electroplating an insulating liner of a photosensitive polymer, the etch-back step can be avoided and the lithography step can be only limited to the liner exposure and the standard develop step. Electroplating ensures full coverage and a constant insulating liner thickness. Because the photoresist is insulating, the process is self-terminating as all conducting surfaces are covered with the insulator, preventing further plating.

Following deposition of the insulating liner, as shown in FIG. 10E, the insulating liner on the surface of the substrate and on the top of the vias is etched away leaving the insulating liner only on the via sidewalls 1007a and within the recesses 1007b.

As shown in FIG. 10F, a seed layer 1008 is applied over the surfaces of the wafer backside. The seed layer, which can be TiW(500 Å)/Au(2000 Å) provides a conduction path for electroplating.

Metal isolation regions are then defined and formed on the backside surface of the substrate. As shown in FIG. 10G, isolation regions 1009 are photolithographically patterned around the perimeter of each via 1006 and are used to insulate a subsequently deposited metallization on the through-substrate via and a metallization layer deposited on the substrate.

Next, as shown in FIG. 10H, the vias 1006 are filled with metal 1011 and a metallization layer 1010 is applied over the entire backside surface forming via contact regions 1012 and backside metallization regions 1010.

As shown in FIG. 10I, the isolation resist can be dissolved in a chemical stripper and the metal regions on top of the resist lifted off. The resist is stripped to the seed layer 1008. The seed layer 1008 is then etched back to the bare substrate 1001 to physically and electrically isolate the backside metal 1010 and the via contact metal regions. 1012

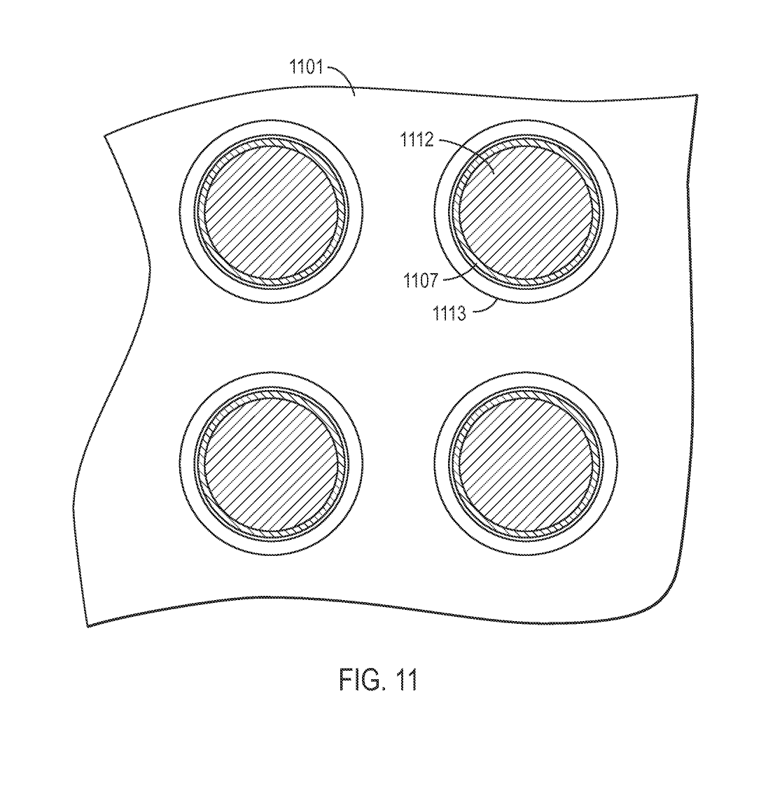

A top view of the semiconductor structure of FIG. 10I is shown in FIG. 11, including backside metal 1101, and via contact metal regions 1112 and insulating liner 1107, separated by backside isolation regions 1113.

Finally, it should be noted that there are alternative ways of implementing the embodiments disclosed herein. Accordingly, the present embodiments are to be considered as illustrative and not restrictive. Furthermore, the claims are not to be limited to the details given herein, and are entitled their full scope and equivalents thereof.

What is claimed is:

1. A multi junction solar cell device, comprising:
a substrate comprising a front side surface and a backside surface;
an epitaxial region overlying the substrate, wherein the epitaxial region comprises at least one multi junction solar cell;
a plurality of cap regions overlying the epitaxial region;
a metal region overlying each of the plurality of cap regions;
a plurality of recesses within the backside surface of the substrate, wherein each of the plurality of recesses corresponds to one of the metal regions;
a through-substrate via extending through the epitaxial region and the substrate from the metal region to the corresponding recess;
an electrically insulating liner disposed on the sidewalls of each of the through-substrate vias and within the corresponding recess;
a via metal contact corresponding to each of the through-substrate vias;
a backside metal on the backside substrate surface;
an insulating region between each of the via metal contacts and the backside metal;
an electrically conductive metal within each of the through-substrate vias electrically connecting each of the plurality of cap regions with the corresponding via metal contact;
wherein the via metal contacts and the backside metal layer form a substantially planar surface.

2. The multi junction solar cell device of claim 1, wherein the electrically insulating liner is characterized by a liner thickness and each of the plurality of recesses is characterized by a recess depth, wherein the liner thickness is about the same as the recess depth.

3. The multi junction solar cell device of claim 1, wherein the electrically insulating liner comprises a photosensitive polymer.

4. The multi junction solar cell device of claim 1, wherein the electrically insulating liner is electroplated.

5. The multi junction solar cell device of claim 1, wherein the substrate is an electrically conductive semiconductor.

6. The multi junction solar cell device of claim 1, wherein the substrate is a semi-insulating semiconductor.

7. The multi junction solar cell device of claim 1, comprising an optical cover material overlying the plurality of cap regions and the epitaxial region.

8. The multi junction solar cell device of claim 3, wherein at least some of the via metal contacts are interconnected.

9. The multi junction solar cell device of claim 1, comprising metal gridlines along cap regions that extend from exposed metal of the through-via region on the top side of the device.

10. The multi junction solar cell device of claim 1, wherein the via metal contacts and the backside metal are separated by an insulator.

11. The multi junction solar cell device of claim 1, comprising a seed layer overlying the insulating liner.

12. The multi junction solar cell device of claim 1, comprising a dielectric material overlying at least a portion of the metal regions, the cap regions, the front side substrate surface, or a combination of any of the foregoing.

13. A method of forming a multi junction solar cell device, comprising:
providing an electrically conductive semiconductor substrate comprising:
a topside surface and a backside surface;
an epitaxial region overlying the substrate, wherein the epitaxial region comprises at least one multi junction solar cell;
a plurality of cap regions overlying the epitaxial region; and
a metal region overlying each of the cap regions;
providing a plurality of recesses in the backside surface of the substrate, wherein each of the plurality of recesses corresponds to one of the plurality of cap regions;
etching through-substrate vias extending from each of the plurality of recesses to the corresponding cap region;
providing an insulating liner within the sidewalls of each of the plurality of through-substrate vias and within each of the recesses;
providing an electrically conductive metal within each of the through-substrate vias; and
providing via metal contacts and a backside metal to provide a metallized backside surface;
wherein the metallized backside surface is substantially planar.

14. The method of claim 13, comprising, before providing a plurality of recesses:
bonding a cover glass on the front side surface of the device; and
thinning the substrate.

15. The method of claim 13, wherein bonding comprises:
applying a planarization adhesive over the front side surface of the device; and
bonding a cover glass to the adhesive.

16. The method of claim 13, comprising, after providing an insulating liner, providing a seed layer on the insulating liner and on the backside surface of the substrate.
